(19) United States
(12) Patent Application Publication
(10) Pub. No.: US 2002/0192914 A1
(43) Pub. Date: Dec. 19, 2002

(54) CMOS device fabrication utilizing selective laser anneal to form raised source/drain areas

(76) Inventors: Isik C. Kizilyalli, Millburn, NJ (US); Joseph R. Radosevich, South Portland, ME (US); Pradip Kumar Roy, Orlando, FL (US)

Correspondence Address: CHRISTIE, PARKER & HALE, LLP, 350 WEST COLORADO BOULEVARD, SUITE 500, PASADENA, CA, 91105, US

(21) Appl. No.: 09/882,367

(22) Filed: Jun. 15, 2001

(51) Int. Cl. H01L 21/336; H01L 29/76; H01L 29/94; H01L 31/062; H01L 31/113; H01L 31/119; H01L 21/20; H01L 21/36; C30B 1/00

(52) U.S. Cl. 438/300; 438/487; 257/368

(57) ABSTRACT

A method for CMOS device fabrication utilizes selective laser annealing to form raised source/drain contact structures. The raised source/drain contact structures provide for an increased contact area to the source/drain impurity regions. The method includes forming an amorphous silicon layer over the substrate and contacting the substrate surface in the source/drain regions. Dopant impurities are preferably introduced into the amorphous silicon layer. A laser annealing process using an excimer laser, selectively anneals the exposed amorphous silicon and is non-absorptive by other exposed materials so that the other materials are not heated past their respective heating critical points. The laser annealing process preferably urges the diffusion of the dopant impurities from the liquified silicon layer into the substrate in the source/drain regions, thereby forming source/drain impurity regions with shallow junction depths and low sheet resistivity. The melted silicon film is allowed to cool and the solidification process urges the silicon film to crystalize upon solidification.

### FIELD OF THE INVENTION

The present invention relates, most generally, to semiconductor devices and methods for manufacturing the same. More particularly, the present invention relates to a method and structure for producing high quality, shallow source/drain junctions and raised source/drain contact structures for advanced CMOS (complementary metal oxide semiconductor) processing.

### BACKGROUND OF THE INVENTION

In today's semiconductor manufacturing industry, there is a driving trend towards increased levels of integration and reduced device and feature sizes. A semiconductor device of tantamount importance in virtually all integrated circuits is the transistor. As such, there is a drive to reduce transistor sizes and integrate as many transistors into a fixed substrate region as possible. It is therefore a challenge to reliably produce transistors having smaller feature sizes. It is similarly a challenge to provide good ohmic contact to the various features of the transistor, most particularly the source/drain regions and the transistor gate. In support of the drive to reduce feature sizes, and also as a general consideration, it is desirable to produce source/drain regions of the transistor which include shallow junctions, high junction breakdown voltages, and which are defect free and include a high dopant concentration and a low sheet resistivity for providing good ohmic contact to the source/drain region.

Source/drain regions are conventionally formed using the pre-formed transistor gate as a self-alignment feature and are created by ion implantation into regions of the substrate which are adjacent the transistor gate. Such ion implantation processes typically cause implant damage by disrupting the interstitial states of the material which is directly subjected to the implantation process. Therefore, there is a need to form source/drain regions with shallow source/drain junctions and which do not include interstitial implant damage. It would also be desirable to provide such a structure having low sheet resistivity and to which high quality ohmic contact can be reliably made.

Also in today's semiconductor manufacturing industry, various other materials such as metal gates and high-K dielectric materials are available and offer several device and processing advantages and increase the versatility of integrated circuit devices which may be formed. Many of these generally desirable materials, however, also include associated shortcomings which limit their utilization due to other processing and device concerns which must be addressed. For example, while metal transistor gates offer many advantages, they generally preclude the subsequent formation of self-aligned source/drain regions after the metal gate is formed. This is because annealing is typically required after the formation of the source/drain areas and any implant anneal processes or other high temperature diffusion processes performed after formation of the metal gate may melt and destroy the metal gate. High-K dielectric materials offer several advantages in forming versatile and high-speed integrated circuit devices, but these materials also are not compatible with subsequent high-temperature processing.

It is therefore desirable to produce a transistor device having high quality source/drain regions which include shallow junctions and to which good ohmic contact can be made. It would also be desirable to produce such structures using the technology compatible with metal gates and the use of high-K dielectric materials. The present invention addresses these concerns.

### SUMMARY OF THE INVENTION

To achieve these and other objects, and in view of its purposes, the present invention provides a method for forming source/drain structures which include shallow junction source/drain impurity regions. The formed source/drain structures also include raised source/drain contact structures. The method includes forming an amorphous silicon layer over and in contact with source/drain regions, then converting the amorphous silicon layer to a crystalline silicon layer by use of selective laser annealing. The selective laser annealing process preferably converts the amorphous silicon to crystalline silicon without melting other device features. In a preferred embodiment, the laser annealing also causes dopant impurities introduced into the amorphous silicon layer prior to the annealing process, to diffuse into the substrate to form defect-free source/drain regions having shallow junctions. The converted, crystalline silicon layer is then preferably patterned to form raised source/drain contact structures which may extend over insulating features formed adjacent the source/drain areas, thereby increasing the area and alignment tolerance for contacting the source/drain region.

### BRIEF DESCRIPTION OF THE DRAWING

The present invention is best understood from the following detailed description when read in conjunction with the accompanying drawing. It is emphasized that, according to common practice, the various features of the drawing are not to scale. On the contrary, the dimensions of the various features are arbitrarily expanded or reduced for clarity. Like numbers denote like elements throughout the figures and text. Included in the drawing are the following figures, each being a cross-sectional view showing the structure being formed.

FIGS. 1-8 show an exemplary process sequence of the method of the present invention. FIG. 1 shows a transistor gate formed between isolation trenches on a semiconductor substrate;

FIG. 2 shows the structure shown in FIG. 1 after a dielectric film has been formed over the structure;

FIG. 3 is a cross-sectional view showing the structure shown in FIG. 2 after portions of the substrate surface have been exposed;

FIG. 4 shows the structure in FIG. 3 after an amorphous silicon film has been added and shows a portion of the amorphous silicon film being subjected to ion implantation;

FIG. 5 shows the transistor structure after portions of the amorphous silicon film have been removed;

FIG. 6 shows the structure in FIG. 5 after the amorphous silicon film has been converted to a crystalline silicon film;

FIG. 7 shows the structure shown in FIG. 6 after additional portions of the crystalline silicon film have been removed; and

FIG. 8 shows the structure shown in FIG. 7 after a dielectric film has been added over the structure and contacts to the transistor gate and source/drain regions have been formed in the dielectric film.

### DETAILED DESCRIPTION OF THE INVENTION

The present invention provides for forming source/drain impurity regions having shallow junctions, and also provides raised source/drain contact structures for providing contact to the source/drain regions. The source/drain regions formed in the substrate are relatively defect free. The raised source/drain contact structures provide an increased area for contacting the source/drain regions. The source/drain impurity regions are preferably doped by forming an amorphous silicon layer over the source/drain regions and contacting the surface of the source/drain regions, introducing dopant impurities into the amorphous silicon layer, then using a selective laser annealing process to selectively melt the silicon film and urge the diffusion of the dopant impurities into the substrate, creating the source/drain impurity regions with shallow junctions within the substrate.

The selective laser annealing process is chosen to selectively anneal (melt) only exposed silicon. Other features such as dielectrics and metals which are formed on the substrate and which may be exposed to the laser radiation, are non-absorptive to the laser radiation or preferably reflect the laser radiation. As such, the selective laser annealing process does not cause other device features to become heated past their critical point of heating. A spatially homogenized laser beam may include a beam size chosen to be large enough to blanket expose the entire substrate in a single exposure. Alternatively, the laser beam may scan the surface to irradiate the complete surface. A masking feature to spatially limit or direct the laser beam, is not needed. After the amorphous silicon film is heated past its melting temperature, the cooling conditions are chosen so that the solidification process utilizes the contact made between the film and the underlying crystalline silicon substrate as a crystal seed which urges the conversion of the amorphous silicon film into a polysilicon or single crystalline film. In the preferred embodiment, an XeCl excimer laser which emits light having a wavelength at the absorption peak of silicon—308 nanometers, is used to irradiate the structure.

Such a process produces an ordered grain structure in the silicon film contacting the source/drain region. High-quality ohmic contact can be made to the source/drain region by contacting the raised, converted silicon film. In an exemplary embodiment, the raised crystalline silicon film may extend laterally over isolation structures formed in or on the substrate. This effectively increases the contact area to which the source/drain region may be contacted.

According to another aspect of this invention, the amorphous silicon film may be converted to a crystalline silicon film prior to the introduction of dopant impurities into the film. The source/drain regions, according to this embodiment, are later formed by implanting the source/drain regions of the substrate through the crystalized silicon film formed above the substrate. In this embodiment in which the source/drain regions in the substrate are not created by diffusion from the silicon film, but rather, by implanting through the crystalized silicon film, implant defects may result in the silicon film directly exposed to the ion implantation process, but the source/drain regions in the substrate are substantially defect-free.

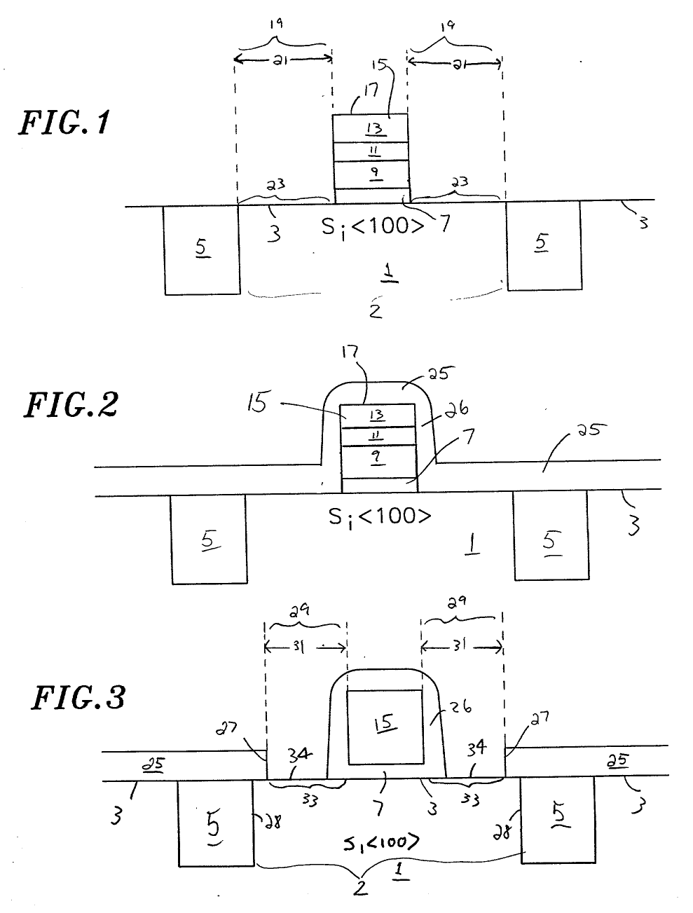

FIGS. 1-8 are used to illustrate the various exemplary embodiments of the sequence of process operations according to the present invention.

FIG. 1 shows an exemplary transistor gate formed over a substrate. Substrate 1 is a <100> silicon substrate. According to an alternative embodiment, a <111> silicon substrate may be used. Substrate 1 includes surface 3. Within substrate 1 are isolation trenches 5. Isolation trenches 5 may be formed by various suitable conventional methods and are filled with insulating materials such as oxides and other dielectrics. According to the exemplary embodiment, transistor region 2 is the substrate region between isolation trenches 5. According to other exemplary embodiments, and as will be suggested in FIG. 3, transistor region 2 may be defined in other ways. Centrally formed within transistor region 2 is transistor gate 15 which is formed over gate dielectric 7. Gate dielectric 7 may be an oxide film or other dielectrics such as high-K dielectric materials. Gate dielectric 7 may be formed using conventional processing techniques. Transistor gate 15 is formed over gate dielectric 7 and is a tri-level material in the exemplary embodiment. According to other exemplary embodiments, a single material may be used to form transistor gate 15. According to one exemplary embodiment, transistor gate 15 may be formed of a single metal film. According to another exemplary embodiment, transistor gate 15 may be a two-level film structure, including a hard mask film formed over a metal film.

In the embodiment shown in FIG. 1, transistor gate 15 includes hard mask film 13 formed over barrier film 11 formed, in turn, over polysilicon film 9. Polysilicon film 9 may be a doped or undoped material and barrier film 11 may be a tungsten or tantalum silicide material according to various exemplary embodiments. According to other exemplary embodiments, other materials may be used to form the various component films of transistor gate 15. Transistor gate 15 and gate dielectric 7 may be formed and patterned using conventional techniques. Transistor gate 15 includes hard mask film 13 which aids in patterning the gate structure and may be formed according to conventional techniques. Transistor gate 15 includes top surface 17.

Source/drain areas 19 are the areas within transistor region 2 which are adjacent to and extend laterally outward from transistor gate 15. Generally speaking, the source/drain impurity regions are the impurity regions which will be formed in the substrate in source/drain areas 19 and adjacent the gate/channel region. The source/drain areas are generally defined in terms of the width of those impurity regions. Such width is generally determined by the location of the blocking features, such as insulating structures, for example, isolation trenches 5 shown of the exemplary embodiment in FIG. 1. Such blocking features bound the active substrate regions into which the source/drain dopant impurities may be introduced. Source/drain areas 19 include width 21. Source/drain areas 19 include source/drain surface 23 which is the portion of surface 3 within source/drain areas 19. It is understood that the channel region of the transistor is the region in substrate 1 subjacent gate dielectric 7 and which extends essentially between opposed source/drain areas 19.

Now turning to FIG. 2, dielectric film 25 is formed over the structure shown in FIG. 1. Dielectric film 25 may be an oxide film, or it may be a composite film of a silicon nitride layer formed over an oxide layer. According to other exemplary embodiments, dielectric film 25 may be formed of other materials. Conventional formation techniques may be used. Dielectric film 25 may alternatively be referred to as a blocking dielectric. The reader is reminded at this point that like numerals designate like features throughout the specification and figures. Dielectric film 25 is formed over surface 3 and transistor gate 15 and includes portions 26 which cover the sides of transistor gate 15.

Dielectric film 25 is then patterned as shown in FIG. 3. Conventional patterning and etching techniques may be used to remove portions of dielectric film 25 from transistor region 2. In the preferred embodiment, a masking film such as photoresist may be formed and patterned then the patterned structure etched using conventional techniques to form the structure shown in FIG. 3. Sections of patterned dielectric film 25 encroach transistor region 2. According to other exemplary embodiments, inner edges 27 of dielectric film 25 may be coincident with inner edges 28 of isolation trenches 5. According to another exemplary embodiment, inner edges 27 may be formed outside inner edges 28. Etched dielectric film 25 includes sidewall spacer sections 26 which aid in isolating the source/drain impurity regions from one another as they are subsequently formed in the substrate.

According to the exemplary embodiment shown in FIG. 3, then, the exemplary source/drain areas within transistor region 2 have been redefined. Source/drain areas 29 represent the regions adjacent transistor gate 15 within transistor region 2 and which extend to an isolation structure formed in or on the substrate 1. According to the exemplary embodiment shown in FIG. 3, source/drain areas 29 which include width 31 extend from transistor gate 15 to inner edge 27 of dielectric film 25. Source/drain surface 33 is the portion of surface 3 within source/drain areas 29. Source/drain surfaces 33 include exposed portions 34. It should be understood that such designation is intended to be arbitrary and the actual source/drain impurity regions are the impurity regions actually formed within the substrate generally adjacent to transistor gate 15 and situated such that current can be made to flow from one source/drain impurity region to the other through a channel region (not shown) formed beneath transistor gate 15. Once formed within substrate 1, the source/drain impurity regions will include lateral boundaries generally defined by the width of the dopant impurity region introduced into the substrate. Preferably, the inner boundaries will be generally adjacent the transistor gate, such as transistor gate 15, and the outer boundaries may be determined by a physical structure such as an isolating region such as dielectric film 25 or isolation trench 5 which defines the edge of the region of the silicon substrate into which dopant impurities are introduced. Spacers 26 may aid in defining the substrate surface into which dopant impurities may be introduced and take into account any lateral diffusion properties which become manifest during anneal, for example.

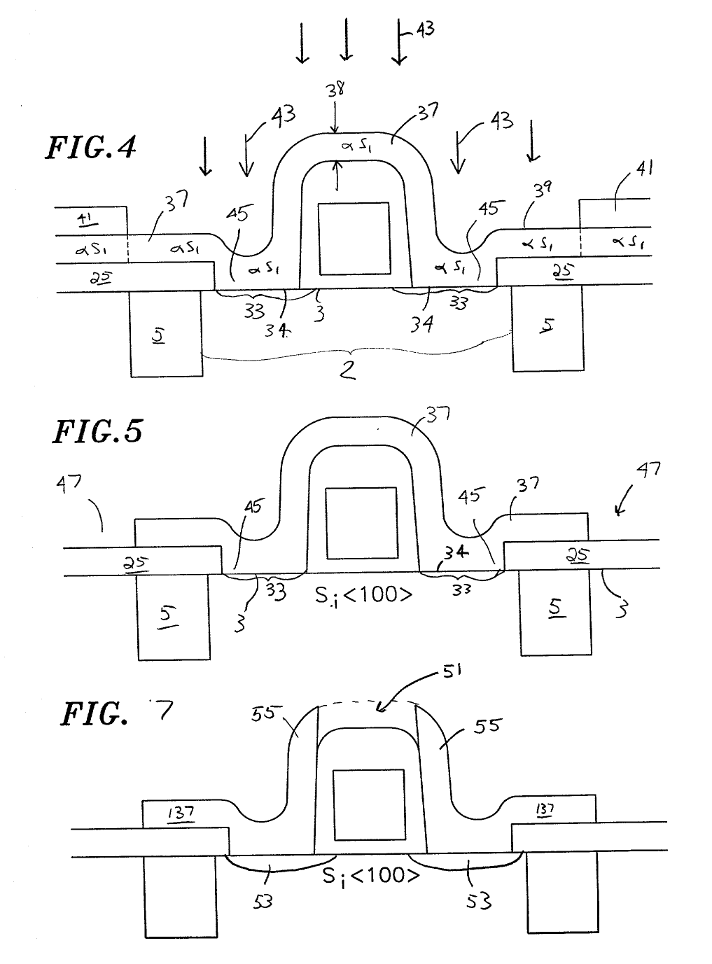

Now turning to FIG. 4, amorphous silicon film 37 is formed over the structure shown in FIG. 3. As such, amorphous silicon film 37 is formed within transistor region 2 and source/drain areas 29. Amorphous silicon film 37 includes contact portions 45 which contact exposed portions 34 of source/drain surfaces 33. Various suitable conventional methods may be used to form amorphous silicon film 37. According to various exemplary embodiments, CVD (chemical vapor deposition), PVD (physical vapor deposition), or PECVD (plasma enhanced CVD) techniques using silane gas, SiH₄, may be used. Amorphous silicon film 37 includes thickness 38 chosen in conjunction with the processing parameters which will subsequently be used for irradiating the surface with laser light and in conjunction with the processing parameters used to introduce dopant impurities into either amorphous silicon film 37 or into each of amorphous silicon film 37 and source/drain surface 33. Thickness 38 is chosen such that the entire depth of amorphous silicon film 37 will be melted when irradiated with laser light, and subsequently cooled to a crystalline silicon material.

In the preferred embodiment shown in FIG. 4, patterned masking film 41 may be formed over surface 39 of amorphous silicon film 37. Conventional techniques may be used. After patterned masking film 41 is formed, ion implantation (indicated by arrows 43) may be used to introduce dopant impurities into amorphous silicon film 37 in regions not covered by masking film 41. In an exemplary embodiment, masking film 41 may be a photosensitive material. Conventional ion implantation processes may be used to introduce dopant impurities into amorphous silicon film 37. N-type or P-type dopant impurities may be introduced depending on the type of source/drain region desired to be formed.

High energy ion implantation processes may be used because any implant damage caused by the ion implantation process will be in amorphous silicon film 37 and not in substrate 1 in which source/drain impurity regions will subsequently be formed. Any implant defects introduced into amorphous silicon film 37 at this point will be later cured when amorphous silicon film 37 is heated and converted to a crystalline silicon film. Such annealing process may simultaneously urge the diffusion of dopant impurities from the silicon film into the silicon substrate. After the introduction of dopant impurities into amorphous silicon film 37, masking film 41 is removed using conventional methods. According to other exemplary embodiments, the ion implantation process may be deferred until a later stage in the processing sequence.

Now turning to FIG. 5, amorphous silicon film 37 has been patterned to form a discrete film section. Conventional patterning and etching techniques may be used to remove portions of amorphous silicon film 37 from outlying regions 47, for example, thereby producing a discrete segment of amorphous silicon film 37. According to other exemplary embodiments, this patterning process may be deferred until after laser annealing is used to convert the amorphous silicon layer to a crystalline silicon layer.

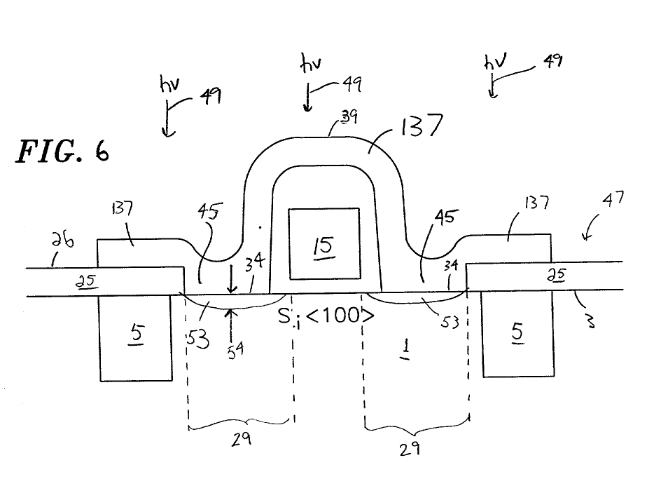

Now turning to FIG. 6, the structure shown in FIG. 5 is subjected to selective laser annealing. During the selective laser annealing process, the structure is irradiated with laser light 49. Although shown in a substantially vertical direction with respect to horizontal substrate 1, laser light indicated by arrows 49 may be directed to the exposed surfaces from above, at various angles. The beam size of the laser is chosen such that the entire substrate 1 may be simultaneously irradiated by a laser beam which is preferably spatially homogeneous. According to other embodiments, a beam with a smaller beam size is scanned over the entire substrate surface. By exposing the substrate surface with laser light or a laser beam, it is meant that the laser light, also known as the radiation emitted by the laser, is incident upon surface 3 and/or the materials formed thereover. In the exemplary embodiment shown in FIG. 6, surface 26 of dielectric film 25 and surface 39 of original amorphous silicon film 37 —hereby converted to crystalline silicon film 137, are directly exposed to the laser light or radiation. It should be understood that, according to other exemplary embodiments, various other structures formed of various materials may be formed on or over surface 3 and may be directly irradiated with laser light.

Masking or spatially limiting techniques are not necessary. In the preferred embodiment, an excimer laser is used. Also in the preferred embodiment, laser irradiation 49 may be provided using an XeCl excimer laser which emits light having a wavelength of 308 nm. According to other exemplary embodiments, other excimer lasers, such as an ArF laser operating at 193 nm or a KrF laser operating at 248 nm, may be used alternatively. Pulse duration of the laser may vary and may range from 10-30 nanoseconds in an exemplary embodiment. Single or multiple pulses may be used. Various repetition rates may be used for multiple-pulsed embodiments. In an exemplary embodiment, a repetition rate of 5 Hz may be used. An exemplary radiation source is a Q-switched excimer laser which emits radiation at a wavelength at or near the absorption peak of silicon, 308 nm. The radiation wavelength is also selected to be non-absorptive when incident upon other materials formed on the substrate so that substantially smaller or no temperature elevation occurs in regions where higher temperatures could degrade materials properties, or device performance. For example, laser radiation conditions are chosen such that substantially the entire depth of original, amorphous silicon film 37 is melted while metal materials, such as may be used in transistor gate 15 according to various exemplary embodiments, will not melt. Radiation conditions and thickness 38 of original amorphous silicon film 37 are chosen such that subjacent materials, such as transistor gate 15 which may be formed of metal in various embodiments, and other exposed materials, such as dielectric film 25 and other features not shown, will not be melted or otherwise degraded by heating past their critical temperatures due to the melting of original amorphous silicon film 37.

Various energy fluences may be used depending on the number, frequency, and duration of pulses, the thickness of original amorphous silicon film 37, and the various structures and films exposed on the substrate. According to various exemplary embodiments, energy fluences ranging from 100 to 600 mJ/cm² may be used. An advantage of the present invention is that various other structures and/or impurity regions may be formed or introduced into the substrate prior to the laser irradiation step. Since original amorphous silicon film 37 melts at a temperature 950° C., much less than the melting temperature of single crystal silicon, the radiation energy is controlled to maintain heating of the silicon substrate below its critical melting temperature, in areas where surface 3 of substrate 1 is exposed.

During the laser irradiation, the entire thickness 38 of original amorphous silicon film 37 is heated by laser radiation at or near the absorption peak of silicon, which causes the entire profile of amorphous silicon film 37 to melt. After the entirety of amorphous silicon film 37 melts, it is then allowed to cool. The solidification conditions, such as the cooling time and temperature gradient, are chosen and controlled such that exposed portion 34 of surface 3 which contacts contact portions 45, acts as a seed urging the original amorphous silicon film to solidify and form crystalline silicon film 137. According to one exemplary embodiment, conditions may be chosen such that crystalline silicon film 137 is a polycrystalline silicon film. According to another exemplary embodiment, conditions may be chosen such that crystalline single film 137 is a single-crystalline silicon film. According to the exemplary embodiment in which crystalline silicon film 137 is a single-crystal silicon film, it will be of the same lattice structure (<100>or <111>) as the silicon substrate.

According to the embodiment, such as described in FIG. 4, in which dopant impurities have been introduced into original amorphous silicon film 37 prior to the laser annealing step shown in FIG. 6, the laser annealing process also urges the diffusion of dopant impurities from the silicon film and into substrate 1 through exposed portions 34 within source/drain areas 29. Source/drain impurity regions 53 are thereby formed within source/drain areas 29 and are therefore self-aligned. Source/drain impurity region 53 includes a shallow junction indicated by depth 54. Depth 54 may be less than or equal to 2000 angstroms in the preferred embodiment. Advantageously, the sheet resistivity of source/drain impurity regions 53, will be low and the source/drain impurity regions 53 will be free of implant damage.

According to another exemplary embodiment in which original amorphous silicon film 37 had not been implanted with dopant impurities prior to the laser annealing step, source/drain impurity regions 53 may be formed at this point by patterning to isolate source/drain areas 29, then using an ion implantation process to introduce dopant impurities into and through crystalline silicon layer 137 and into substrate 1 in source/drain areas 29. In this manner, source/drain impurity regions 53 will also be substantially free of implant defects.

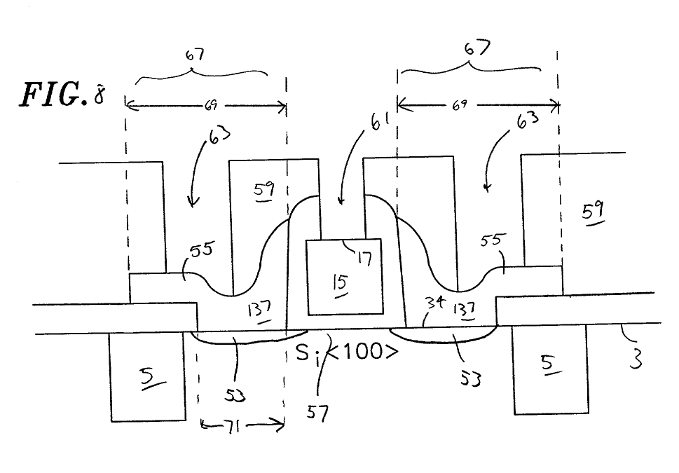

Now turning to FIG. 7, conventional patterning techniques are again used to remove portion 51 (indicated by the dashed lines) of crystalline silicon film 137. According to another exemplary process sequence of the present invention, this additional patterning operation may have been carried out prior to the irradiation by laser light as discussed in conjunction with FIG. 6. According to still another exemplary embodiment in which the patterning process discussed in conjunction with FIG. 5, had not yet been carried out to form a discrete portion of the silicon film prior to laser annealing, a single patterning process may now be used to form discrete sections of the crystal silicon film 137. The patterning process produces raised source/drain contact structures 55. Raised source/drain contact structures 55 are portions of crystalline silicon film 137 and are in contact with source/drain impurity regions 53.

Now referring to FIG. 8, upper insulating film 59 is formed over the structure shown in FIG. 7, then patterned, using conventional methods. Upper insulating film 59 includes opening 61 through which contact to top surface 17 of transistor gate 15 may be made. Upper insulating film 59 also includes openings 63 through which contact to raised source/drain contact structures 55 may be made. Raised source/drain contact structures 55 include width 69. Width 69 is greater than corresponding width 71 of exposed portion 34 of surface 3. In this manner, a looser alignment tolerance is created for contacting source/drain impurity region 53 since they may be contacted by contacting superjacent source/drain contact structures 55 which include a width 69 greater than the corresponding width 71 of exposed portion 34 of surface 3. The area to which contact can be made to source/drain impurity region 53 is therefore increased.

Although shown and described in terms of two opposed source/drain regions of a single transistor, it should be understood that the structure and process sequence of the present invention may be used to form a single source/drain impurity region and corresponding raised source/drain contact structure, they may be used to simultaneously form a plurality of similar structures on a substrate, and they may be used to form either or both of the source/drain regions associated with a transistor on a plurality of transistors.

The preceding merely illustrates the principles of the invention. It will thus be appreciated that those skilled in the art will be able to devise various arrangements which, although not explicitly described or shown herein, embody the principles of the invention and are included within its spirit and scope. Furthermore, all examples and conditional language recited herein are principally intended expressly to be only for pedagogical purposes and to aid the reader in understanding the principles of the invention and the concepts contributed by the inventors to furthering the art, and are to be construed as being without limitation to such specifically recited examples and conditions. Moreover, all statements herein reciting principles, aspects, and embodiments of the invention, as well as specific examples thereof, are intended to encompass both structural and functional equivalents thereof. Additionally, it is intended that such equivalents include both currently known equivalents and equivalents developed in the future, i.e., any elements developed that perform the same function, regardless of structure. The scope of the present invention, therefore, is not intended to be limited to the exemplary embodiments shown and described herein. Rather, the scope and spirit of the present invention is embodied by the appended claims.

1. A method for forming a raised source/drain contact structure for a semiconductor transistor, comprising the steps of:
providing a transistor gate on a substrate surface, and a source/drain region defined as a surface region extending laterally from said transistor gate to an isolation structure formed one of on and in said substrate;
forming an amorphous silicon layer over and contacting said source/drain region and over said isolation structure;
converting said amorphous silicon layer to a crystalline silicon layer using selective laser annealing; and
patterning said crystalline silicon layer to form a raised source/drain contact structure covering said source/drain region and extending over at least part of said isolation structure.

2. The method as in claim 1, in which said amorphous silicon layer includes dopant impurities therein prior to said step of converting, and said step of converting urges at least some of said dopant impurities to diffuse into said source/drain region.

3. The method as in claim 1, further comprising the step of forming an insulating layer over said raised source/drain contact structure and forming at least one contact opening through said insulating layer to expose a corresponding portion of said raised source/drain contact structure, each portion including sections of said corresponding raised source/drain contact structure formed over said corresponding isolation structure.

4. The method as in claim 1, wherein the step of converting comprises converting said amorphous silicon layer to a polycrystalline silicon layer.

5. The method as in claim 1, wherein the step of converting comprises converting said amorphous silicon layer to a substantially single crystalline silicon layer.

6. The method as in claim 1, wherein said step of converting comprises using an excimer laser for said selective laser annealing.

7. The method as in claim 6, in which said step of converting includes an XeCl excimer laser emitting light having a wavelength of approximately 308 nanometers.

8. The method as in claim 6, wherein said excimer laser emits radiation at or near the absorption peak of silicon.

9. The method as in claim 8, in which said transistor gate comprises a metal gate and said step of converting does not melt said metal gate.

10. The method as in claim 1, in which said step of providing a transistor gate includes said transistor gate being covered by an insulating material.

11. The method as in claim 1, further comprising removing sections of said amorphous silicon layer thereby forming at least one discrete section of amorphous silicon, prior to said step of converting.

12. The method as in claim 1, further comprising implanting impurities into said crystalline silicon layer and said source/drain region after said step of converting.

13. A method for forming a raised source/drain contact structure for a semiconductor transistor, comprising the steps of:
providing a transistor gate on a substrate surface and a source/drain region, defined as a surface region extending laterally from said transistor gate to an isolation structure formed one of on and in said substrate;
forming an amorphous silicon layer over and contacting said source/drain region and said isolation structure;
patterning said amorphous silicon layer to form a raised source/drain contact structure covering said source/drain region and extending over at least part of said isolation structure; and
converting said amorphous silicon raised source/drain contact structure to a crystalline silicon raised source/drain contact structure.

14. The method as in claim 13, in which said amorphous silicon layer includes dopant impurities therein prior to said step of converting, and said step of converting urges at least some of said dopant impurities to diffuse into said source/drain region.

15. The method as in claim 13, wherein said step of converting comprises using an excimer laser for said selective laser annealing.

16. The method as in claim 15, wherein said excimer laser emits radiation at or near the absorption peak of silicon.

17. A method for forming raised source/drain contact structure for a semiconductor transistor, comprising the steps of:
providing a transistor gate on a substrate surface, and opposed source/drain regions, each source/drain region defined as the surface region extending laterally from said gate to a corresponding isolation structure formed one of on and in said substrate;
forming an amorphous silicon layer over and contacting each said source/drain region and over each said corresponding isolation structure;
converting said amorphous silicon layer to a crystalline silicon layer using selective laser annealing; and
patterning said crystalline silicon layer to form a duality of raised source/drain contact structures, each covering said corresponding source/drain region and extending over at least part of said associated isolation structure.

18. The method as in claim 17, in which said amorphous silicon layer includes dopant impurities therein prior to said step of converting, and said step of converting urges at least some of said dopant impurities to diffuse into said source/drain regions.

19. The method as in claim 17, wherein said step of converting comprises using an excimer laser for said selective laser annealing.

20. A method for forming a semiconductor structure, comprising the steps of:
providing an exposed surface of a semiconductor substrate, said exposed surface bounded laterally by at least one isolation structure;
forming a discrete amorphous silicon layer contacting said exposed surface and extending laterally over at least portions of at least one of said at least one isolation structure; and
selectively laser annealing said discrete amorphous silicon layer, thereby converting said discrete amorphous silicon layer to a discrete single crystalline silicon layer.

21. The method as in claim 20, in which said discrete amorphous silicon layer includes dopant impurities incorporated therein, and step of converting urges at least some of said dopant impurities to diffuse into said exposed substrate surface.

22. The method as in claim 20, wherein said step of selectively laser annealing includes irradiating with light emitted by an excimer laser.

23. The method as in claim 20, in which said step of selectively laser annealing includes using an excimer laser which emits light at a wavelength at or near the absorption peak of silicon, and produces an energy fluence chosen to anneal substantially only said discrete amorphous silicon layer.

24. A method for forming a transistor comprising:
providing a semiconductor substrate having a surface;
providing a transistor region between isolation structures formed in said substrate;
forming a gate stack, including a gate electrode formed over a gate dielectric, in a central portion of said transistor region, said gate stack covered with an insulating material, the lateral portions of said transistor region not covered by said gate stack being designated source/drain regions;
forming a discrete amorphous silicon film over said transistor region, said amorphous silicon film including dopant impurities therein;
irradiating with a laser beam, then allowing cooling, thereby converting said amorphous silicon film to a crystalline silicon film and urging the diffusion of at least some of said dopant impurities into said source/drain regions; and
forming an opposed duality of discrete raised source/drain contact structures from said crystalline silicon film, by removing portions of said crystalline silicon film, each raised source/drain contact structure formed over a corresponding source/drain region.

25. The method as in claim 24, in which said step of forming said discrete amorphous silicon film includes forming said discrete amorphous silicon film over said transistor region and further extending over said isolation structures and in which said step of forming discrete raised source/drain contact structures includes each raised source/drain contact structure extending over said corresponding isolation structure.

26. The method as in claim 24, further comprising forming a dielectric structure over said surface prior to the step of forming said discrete amorphous silicon film, portions of said dielectric structure encroaching said transistor region and in which said step of forming a discrete amorphous silicon film includes forming said amorphous silicon film over at least portions of said dielectric film.
